(19) United States
(12) Patent Application Publication
(10) Pub. No.: US 2015/0243486 A1
(43) Pub. Date: Aug. 27, 2015

(54) PLASMA PROCESSING APPARATUS

(71) Applicant: Hitachi High-Technologies Corporation, Tokyo (JP)

(72) Inventors: Kenetsu Yokogawa, Tokyo (JP); Taku Iwase, Tokyo (JP); Akira Hirata, Tokyo (JP); Masahito Mori, Tokyo (JP); Masakazu Isozaki, Tokyo (JP); Yosuke Sakai, Tokyo (JP); Takahisa Hashimoto, Tokyo (JP)

(73) Assignee: HITACHI HIGH-TECHNOLOGIES CORPORATION

(21) Appl. No.: 14/627,078

(22) Filed: Feb. 20, 2015

(30) Foreign Application Priority Data
Feb. 26, 2014 (JP) 2014-034794

(51) Int. Cl. H01J 37/32; H01L 21/67

(52) U.S. Cl. CPC H01J 37/32183; H01L 21/67069; H01J 37/32155; H01J 37/32697; H01J 37/32715; H01J 37/32559

(57) ABSTRACT

In a plasma processing apparatus including an upper electrode arranged above a sample stage on which a sample to be processed in a processing chamber is mounted to supply an electric field, and a high frequency power supply to output first high frequency power to form the electric field to the upper electrode, an insulating layer has an impedance smaller than the impedance of the feeding path for bias or the feeding path for electrostatic chuck and a current of the first high frequency power flows through a circuit that passes through the conductive plate and a member constituting an inner sidewall surface of the processing chamber from the upper electrode via the top surface of the sample stage to return to the high frequency power supply.

### BACKGROUND OF THE INVENTION

The present invention relates to a plasma processing apparatus that manufactures semiconductor devices by processing a sample to be processed such as a semiconductor wafer chucked after being mounted on a sample stage arranged in a processing chamber inside a vacuum chamber using plasma formed in the processing chamber, and in particular, relates to a plasma processing apparatus that etches a film structure formed from a semiconductor such as silicon or silicon oxide or a material made of dielectrics formed on a sample surface in advance to a desired shape while forming a bias potential by supplying power of a high frequency band to an electrode inside the sample stage.

In a plasma processing apparatus that performs processing such as etching on a substrate-like sample such as a semiconductor wafer as described above, a gas for processing used to process a sample by generating plasma in a processing chamber is introduced while air being exhausted from the processing chamber arranged inside a vacuum chamber by a vacuum pumping unit including a vacuum pump such as a turbo-molecular pump linked to the vacuum chamber, the gas is excited using an electric field or a magnetic field supplied into the processing chamber to generate plasma, and a desired shape is processed by etching a resist made of resin of a film structure arranged on the surface of the sample in advance or a film to be processed other than masks of oxide or the like. As the configuration to generate plasma, in general, inductive coupling, electron cyclotron resonance, and capacitive coupling between plates arranged in parallel (including the magnetron method) are mainly used.

A magnetic field of 13.56 MHz is mainly used for the generation of plasma by inductive coupling and a magnetic field of a micro wave of 2.45 GHz is mainly used for the generation of plasma by electron cyclotron resonance. In the inductive coupling method and the electron cyclotron resonance method, apart from the generation of plasma, in order to promote processing of etching by attracting ions in the plasma to the surface of the sample, an attempt has been made to bring the shape of processing closer to an intended shape by applying an electric field of a high frequency (RF) band to a sample or an electrode inside a sample stage on which the sample is mounted and controlling energy of ions incident on the surface of the sample to desired energy by adjusting the magnitude of RF power to adjust the value of a bias potential formed above the sample.

In the method using parallel plates, on the other hand, an electric field of 13.56 MHz has been used for the generation of plasma, but in recent years, an electric field of VHF band (30 MHz to 300 MHz) is increasingly used to improve the plasma density and to enable plasma generation in a low gas pressure region. Further, apart from the plasma generation, an electromagnetic wave of the RF band that independently controls energy of incident ions on the sample surface is increasingly used.

The frequency of a few hundred kHz to a few MHz has been used as the frequency of the electric field supplied to adjust energy of incident ions by forming the bias potential. Also as the frequency of the electric field for the formation of such a bias potential, a MHz band or higher tends to be used more frequently from the viewpoint of controllability of energy of incident ions.

In such a plasma processing apparatus, to adjust the temperature of the sample being processed to a range appropriate for processing, a film-like electrode that electrostatically chucks a sample by an electrostatic force onto a film made of dielectrics constituting a sample mounting surface in an upper portion of a sample stage whose temperature is within a predetermined range is arranged inside the film made of dielectrics. Further, a gas for heat transfer such as He is supplied from the mounting surface into a space between the backside of the chucked sample and the mounting surface to promote heat transfer between both.

Furthermore, the temperature of a sample stage has been adjusted by refrigerants opposed to each other whose temperature is in a predetermined range being supplied and circulated through a channel arranged concentrically or spirally inside a disc-like or cylindrical base material made of metal constituting the sample stage. In addition to the adjustment of temperature of the sample by the refrigerant, heating by a heater arranged in an upper portion of the sample stage has been used.

As an example of the related art, a plasma processing apparatus described in JP-A-2006-114767 (corresponding to U.S. Pat. No. 7,438,783) has been known. In JP-A-2006-114767, a support table arranged in a plasma processing chamber inside a cylindrical vacuum chamber made of aluminum to support a semiconductor wafer W on the mounting surface as a top surface thereof is included and also an electrostatic chuck constituted by arranging an electrode between insulators to chuck the semiconductor wafer W is included on the mounting surface of the support table so that the semiconductor wafer W is chucked onto the insulators by a Coulomb force after a voltage from a DC power supply being applied to the electrode.

Further, a refrigerant channel to allow a refrigerant to circulate and a gas introducing mechanism that supplies a He gas to make heat transfer between the refrigerant and the semiconductor wafer W more efficient to the backside of the semiconductor wafer W are included in the support table. Further, a high frequency power supply is electrically connected to the support table to supply high frequency power in the range of 13.56 to 150 MHz and also a high frequency power supply that supplies high frequency power in the range of 500 kHz to 13.56 MHz to form a bias potential to attract ions in the plasma is electrically connected. In JP-A-2006-114767, moreover, a confinement plate extending from an outer circumferential side of the support table toward a space inside the plasma processing chamber on the outer side and arranged by surrounding the support table is included and the confinement plate is installed to prevent plasma in the processing chamber above the support table from diffusing toward a space on the downstream side below the support table.

### SUMMARY OF THE INVENTION

In JP-A-2006-114767 described above, problems arose because adequate consideration has not been given to the following points. That is, in JP-A-2006-114767, when plasma is generated in the processing chamber, due to high frequency power output from the high frequency power supply for plasma formation and supplied into the processing chamber, an equivalent circuit in which a current flows between an antenna in a flat shape or an electrode arranged in an upper portion of the processing chamber above the sample stage and the grounded high frequency power supply for plasma formation via the sample stage is formed in the processing chamber.

In terms of an equivalent circuit, such a high frequency current can be considered to flow to the ground by running through a sample on the sample stage or the sidewall or base material made of conductor of the sample stage via a shower plate 5 and plasma 11 of a conductor or semiconductor to diffuse a gas for processing generally arranged below an antenna or an upper electrode and running through the high frequency power supply for bias potential formation. On the other hand, if one end of the power supply for electrostatic chuck or the power supply that supplies power to a heater is electrically connected to the ground or grounded, a portion of power for plasma formation supplied into the processing chamber flows to the ground by passing through a film-like electrode for electrostatic chuck or a heater arranged in the sample stage and a wire for feeding or a path arranged below the sample stage and electrically connected thereto via a connector and also passing through the electrode for electrostatic chuck or the power supply for a heater.

A current of high frequency power for the formation of plasma (hereinafter, called a high frequency current) to such a feeding path can be suppressed by setting a sufficiently high input impedance of the whole feeding path including a low-pass filter and a high frequency power matching box to the high frequency power. If a high frequency band of the VHF band or higher is used for high frequency power for plasma formation, however, stray capacitance or parasitic inductance in each circuit or connection cable has a significant influence and it becomes difficult to realize a sufficiently high input impedance capable of suppressing a high frequency current caused by high frequency power for plasma formation in a stable manner.

If, for example, a coaxial cable is used as a cable that connects the electrode and the low-pass filter, even if the length of the coaxial cable is about 10 cm in one example, the electrostatic capacity between a cable core wire and a shielding wire has a magnitude of about 10 pF, leading to an impedance of about 80Ω to the ground for a current of about 200 MHz in the VHF band. Further, parasitic impedance in the low-pass filter has an influence. Thus, the input impedance in a feeding path using such a cable greatly fluctuates under the influence of variations of characteristics and constants of elements arranged on such a path and the length of wire.

Therefore, power from the high frequency power supply for plasma formation constituting a circuit by passing through and flowing through such a path fluctuates under the influence of the input impedance on a path from the electrode thereof to the ground and due to the fluctuations, power input for forming plasma fluctuates. JP-A-2006-114767 does not take into consideration facts that such fluctuations of power used for forming plasma may degrade reproducibility of conditions for processing a sample, leading to increased fluctuations of a finished shape obtained after processing, or may increase a performance difference (so-called tool-to-tool difference) between plasma processing apparatuses, decreasing yields of processing or reliability of apparatuses.

An object of the present invention is to provide a plasma processing apparatus that improves yields of processing.

The above object is achieved by a plasma processing apparatus including: a processing chamber arranged inside a vacuum chamber; a sample stage arranged in the processing chamber and on a top surface of which a sample to be processed is mounted; an upper electrode arranged above the sample stage and opposite to the top surface of the sample stage to supply an electric field to generate plasma in the processing chamber; a first high frequency power supply electrically connected to the upper electrode to output first high frequency power to form the electric field; a lower electrode arranged inside the sample stage and to which second high frequency power whose frequency is lower than the frequency of the first high frequency power is supplied while the sample being processed; a second high frequency power supply connected to the lower electrode to supply the second high frequency power via a feeding path for bias; an electrode for electrostatic chuck arranged in an upper portion of the sample stage and inside a dielectric film constituting a mounting surface and to which DC power is supplied via a feeding path for electrostatic chuck arranged inside the lower electrode; and a conductive plate arranged by surrounding an outer circumference of the lower electrode across an insulating layer, facing plasma on an outer circumferential side of the sample stage, and to which a ground potential is set, wherein the insulating layer has an impedance smaller than the impedance of the feeding path for bias or the feeding path for electrostatic chuck for the first high frequency power and a current of the first high frequency power flows through a circuit that passes through the conductive plate and a member constituting an inner sidewall surface of the processing chamber from the upper electrode via the top surface of the sample stage to return to the high frequency power supply.

According to the present invention, a circuit for flowing to a vacuum chamber wall from the side face of a processed sample stage via a conductive plate is formed for an electromagnetic wave for plasma formation and the influence of various functional units connected to the processed sample stage can be reduced. Accordingly, fluctuations of plasma generation due to characteristic differences of various functional units connected to the processed sample stage can be suppressed and also degradation of reproducibility and an occurrence of differences between apparatuses can be suppressed.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross sectional view schematically showing an outline configuration of a plasma processing apparatus according to an embodiment of the present invention;

FIG. 2 is a cross sectional view showing a neighborhood of a confinement plate of a sidewall of a sample stage in the embodiment shown in FIG. 1;

FIG. 3 is a cross sectional view schematically showing an outline configuration of a plasma processing apparatus according to a comparative example of the present invention;

FIG. 4 is a cross sectional view schematically showing the flow of a high frequency current for plasma formation in the embodiment shown in FIG. 1;

FIG. 5 is a cross sectional view schematically showing an outline configuration of a modification of the embodiment shown in FIG. 1; and

FIG. 6 is a cross sectional view schematically showing an outline configuration of another modification of the embodiment shown in FIG. 1.

### DETAILED DESCRIPTION OF THE EMBODIMENTS

Hereinafter, the embodiments of the present invention will be described using the drawings.

### First Embodiment

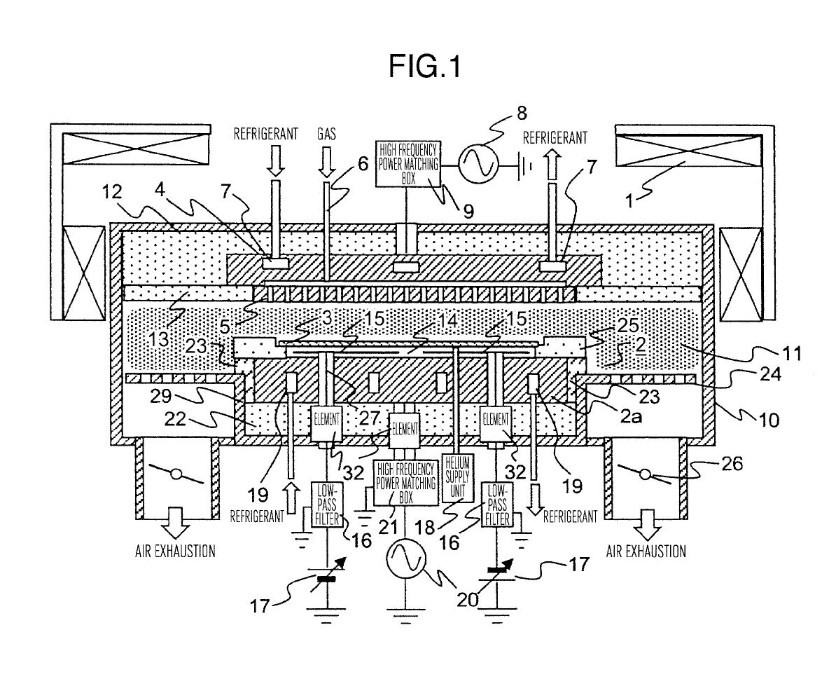

An embodiment of the present invention will be described using FIGS. 1, 2, and 4. FIG. 1 shows a plasma processing apparatus in the present invention. First, the apparatus configuration in FIG. 1 will be described.

The plasma processing apparatus in FIG. 1 is a plasma processing apparatus of magnetic field parallel plate type using a magnetic coil 1 as a solenoid coil. The plasma processing apparatus in the present embodiment includes a vacuum chamber 10 and a processing chamber arranged in an upper portion thereof and in which a sample to be processed is mounted in a space inside the vacuum chamber and plasma is formed after a gas for processing being supplied and also includes a plasma forming unit as an apparatus arranged above the vacuum chamber 10 to generate an electric field or a magnetic field to form plasma inside the processing chamber and an exhaust apparatus connected to a lower portion of the vacuum chamber 10 and including a vacuum pump such as a turbo-molecular pump that reduces pressure by exhausting air inside the processing chamber.

In the processing chamber inside the vacuum chamber 10, an upper electrode 4 in a disc shape to which high frequency power to form plasma is supplied by being arranged above and opposite to a sample stage 2 arranged in a lower portion thereof and having a cylindrical shape and a mounting surface constituting the top surface thereof and on which a sample 3 like a substrate such as a semiconductor wafer is mounted and a shower plate 5 in a disc shape arranged on the sample 3 side of the upper electrode 4 and opposite to the mounting surface of the sample stage 2 and including a plurality of through holes constituting a ceiling surface of the processing chamber to supply a gas into the processing chamber in a distributed manner. The shower plate 5 and the upper electrode 4 as an antenna arranged above the shower plate 5 are arranged such that a gap is formed therebetween when mounted inside the vacuum chamber 10 and a gas for processing supplied into the processing chamber and used for processing of the sample 3 or an inert gas that is not directly used, but is used to dilute the gas for processing or to substitute for the gas for processing by being supplied into the processing chamber while the gas for processing is not supplied is supplied to the gap from a gas introduction line 6 outside the vacuum chamber 10 connected to the gap via a gas channel provided inside the upper electrode 4 and dispersed therein before being supplied into the processing chamber by passing through the plurality of through holes arranged in a region including the center portion of the shower plate 5.

The upper electrode 4 is a member in a disc shape formed of aluminum, stainless or the like as a conductive material, has a coaxial cable to which high frequency power for plasma formation is transmitted electrically connected to the center portion of the top surface, and has an upper electrode refrigerant channel 7 connected to a temperature control apparatus such as a chiller that controls the temperature of the refrigerant to a predetermined range and to which the refrigerant is supplied therein so that the temperature of the upper electrode 4 is adjusted to a range of appropriate values for processing by the refrigerant being circulated therein for heat exchange. The shower plate 5 in the present embodiment is configured by a dielectric such as quartz or a semiconductor such as silicon through which an electric field formed on the surface thereof or discharged therefrom after the high frequency power being applied passes.

High frequency power for plasma formation is supplied to the upper electrode 4 via a high frequency power matching box for discharge 9 from a high frequency (radio frequency) power supply for discharge 8 electrically connected to the upper electrode 4 via the coaxial cable and an electric field is discharged from the surface of the upper electrode 4 into the processing chamber by passing through the shower plate 5. Further, in the present embodiment, a magnetic field formed by the electromagnetic coil 1 arranged outside the vacuum chamber 10 and surrounding above and the side of an upper portion of the processing chamber is supplied into the processing chamber.

Plasma 11 is formed in the processing chamber after atoms or molecular of a gas for processing or an inert gas supplied into the processing chamber being excited by an interaction of the magnetic field and the high frequency electric field. In the present embodiment, power of 200 MHz as a frequency of the very high frequency band (VHF band) is used as high frequency power to form plasma.

The upper electrode 4 is electrically insulated from a cap member constituting an upper portion of the vacuum chamber 10 to open/close the vacuum chamber 10 by an upper electrode insulator 12 in a ring shape arranged above or on the side of the upper electrode 4 constituted of a dielectric such as quartz, Teflon or the like. Similarly, an insulating ring 13 constituted of a dielectric such as quartz is arranged around the shower plate 5 to insulate from the cap member. The upper electrode insulator 12, the insulating ring 13, the upper electrode 4, and the shower plate 5 rotationally moves together with the cap member during operation of opening/closing the cap member.

The sidewall of the vacuum chamber 10 having a cylindrical shape is connected to a transfer container as a vacuum chamber (not shown) in which the pressure is reduced and the sample 2 is transferred and a gate as an opening of a path on which the sample 2 is input/output is arranged therebetween and also a gate valve that airtightly seals the inside of the vacuum chamber 10 when the sample 2 is processed inside the vacuum chamber 10 is arranged.

An opening for air exhaustion communicatively connected to the vacuum pump that exhausts air inside the processing chamber is arranged in a lower portion of the vacuum chamber 10 below the sample stage 2 in the processing chamber, a pressure regulating valve 26 as a valve in a plate shape arranged across a channel to increase/decrease the cross section by rotating around the axis is arranged inside a path of exhaust connecting an exhaust port and the vacuum pump, and the flow rate or speed of exhaust from the processing chamber is increased/decreased by the angle of the rotation being adjusted. The pressure inside the processing chamber is adjusted by a control apparatus (not shown) so as to be within a range of desired values by balancing the flow rate or speed of the gas supplied from the through holes of the shower plate 5 and the flow rate or speed of a gas or particles discharged from an exhaust opening.

Next, the structure around the sample stage 2 will be described. The sample stage 2 in the present embodiment is a stage arranged in the center portion of a lower portion of the processing chamber and having a cylindrical shape and includes a base material 2a having a cylindrical shape or a disc shape and made of metal therein. The base material 2a in the present embodiment is electrically connected to a high frequency (radiofrequency) power supply for bias 20 by a feeding path including a coaxial cable via a high frequency power matching box for bias 21 and thus, high frequency power having a different frequency (4 MHz in the embodiment) from that of the high frequency power for plasma generation is supplied.

Charged particles such as ions in plasma are attracted to the top surface of the sample 3 or the sample mounting surface by high frequency power supplied to the base material 2a and thus, a bias potential is formed above the top surface or the sample mounting surface. That is, the base material 2a functions as a lower electrode to which high frequency power for bias is applied below the upper electrode 4. Inside the base material 2a, a refrigerant channel 19 through which a refrigerant of a predetermined temperature circulates to adjust the temperature of the base material 2a or the sample mounting surface to a temperature appropriate for processing is arranged multiple-concentrically or spirally.

On the top surface of the base material 2a, an electrostatic chuck film 14 containing a tungsten electrode 15 to which DC power is supplied to cause electrostatic chucking of the sample 3 and made of a dielectric such as alumina or yttria is arranged. The tungsten electrode 15 is electrically connected to a DC power supply 17 via a feeding path 27 whose backside is arranged inside a through hole passing through the base material 2a.

An element 32 such as a resistor or coil is arranged below the base material 2a and on the feeding path 27 inside the sample stage 2 and the element 32 is connected to the grounded high frequency power matching box for bias 21 and the high frequency power supply for bias 20 via the high frequency power matching box for bias 21 by a feeding path similarly including a coaxial cable. Further, the element 32 such as a resistor or coil is arranged below the through hole and on the feeding path 27 inside the sample stage 2 and the element 32 is connected to the DC power supply 17 via a grounded low-pass filter 16.

The DC power supply 17 and the high frequency power supply for bias 20 in the present embodiment have a terminal on one side grounded or electrically connected to a ground. The low-pass filter 16 and the high frequency power matching box for bias 21 are arranged to suppress the inflow of high frequency power for plasma formation to the DC power supply 17 and the high frequency power supply for bias 20 from the high frequency power supply for discharge 8. While DC power from the DC power supply 17 and high frequency power from the high frequency power supply for bias 20 are supplied to the electrostatic chuck film 14 and the sample stage 2 without loss respectively by the low-pass filter 16 that prevents the flow of current of higher frequencies for filtering, high frequency power for plasma formation flowing from the sample stage 2 into the DC power supply 17 and the high frequency power supply for bias 20 flows to the ground via the low-pass filter 16 or the high frequency power matching box for bias 21. The low-pass filter 16 is not illustrated on a feeding path from the high frequency power supply for bias 20 in FIG. 1, but a circuit having a similar effect is contained in the illustrated high frequency power matching box for bias 21.

In the configuration as described above, the impedance of power from the high frequency power supply for discharge 8 when the DC power supply 17 and the high frequency power supply for bias 20 are viewed from the sample stage 2 can be set relatively low. In the present embodiment, the impedance of high frequency power for plasma formation when the DC power supply 17 or the high frequency power supply for bias 20 is viewed from base material 2a side of the sample stage 2 can be made higher (in the present embodiment, 100Ω or more) by inserting and arranging the element 32 such as a resistor or a coil that increases the impedance between the low-pass filter 16 or the high frequency power matching box for bias 21 on the feeding path.

In the embodiment shown in FIG. 1, a plurality of the tungsten electrodes 15 arranged inside the electrostatic chuck film 14 is included to perform bipolar electrostatic chucking in which a DC voltage is supplied such that one tungsten electrode and the other have different polarities. Thus, the tungsten electrodes 15 are arranged by dividing the area of a contact surface between the electrostatic chuck film 14 and the sample 3 into two equal regions or regions of values within an approximated range to the extent allowing to consider to be equal and DC power of values independent of each other is supplied and voltages of different values are maintained. A helium gas is supplied by a helium supply unit 18 to between the electrostatic chuck film 14 and the backside of the sample 3 in contact so that heat transfer between the sample 3 and the electrostatic chuck film 14 is improved and the amount of exchanged heat with the refrigerant channel 19 inside the base material 2a is increased to enhance efficiency of adjusting the temperature of the sample 3.

An insulating plate 22 in a disk shape formed of Teflon or the like is arranged below the base material 2a and grounded or electrically connected to a ground and the base material 2a set to the ground potential is insulated from members below. Further, an insulating layer 23 in a ring shape made of dielectric such as alumina is connected and arranged by surrounding the side face of the base material 2a. A conductive plate 29 grounded or electrically connected to a ground, set to the ground potential, and formed of a conductive material is arranged below and around the insulating plate 22 connected to the base material 2a and arranged below the base material 2a and around the above insulating layer 23.

The conductive plate 29 is a plate member having a circular shape or an approximate shape to the extent allowing to consider to be circular when viewed from above, has the base material 2a in the center portion arranged on the inner side across the insulating plate 22 and the insulating layer 23, and includes a recess arranged by being surrounded by the undersurface and the side face of the base material 2a. The conductive plate 29 also includes a confinement plate 24 as a flange portion in a plate shape extending horizontally from the center side to the outer circumferential side in the position on the outer circumferential side of the recess. The confinement plate 24 is arranged to, so to speak, confine plasma formed above the sample stage 2 in the processing chamber by causing the plasma to be present in an upper portion inside the processing chamber and the flange portion in a plate shape includes a plurality of holes to allow gases or particles to pass through in the up and down direction.

Further, in a place on the outer circumferential side of the sample mounting surface having a substantial circular shape of the electrostatic chuck film 14 in an upper portion of the sample stage 2, a susceptor 25 in a ring shape formed of dielectrics having plasma resistance such as quartz is arranged by surrounding the sample mounting surface by being placed on the top surface in an outer circumferential portion of the base material 2a. The susceptor 25 is arranged such that the outer circumferential edge thereof is placed on the top surface of the insulating layer 23 to cover the top surface.

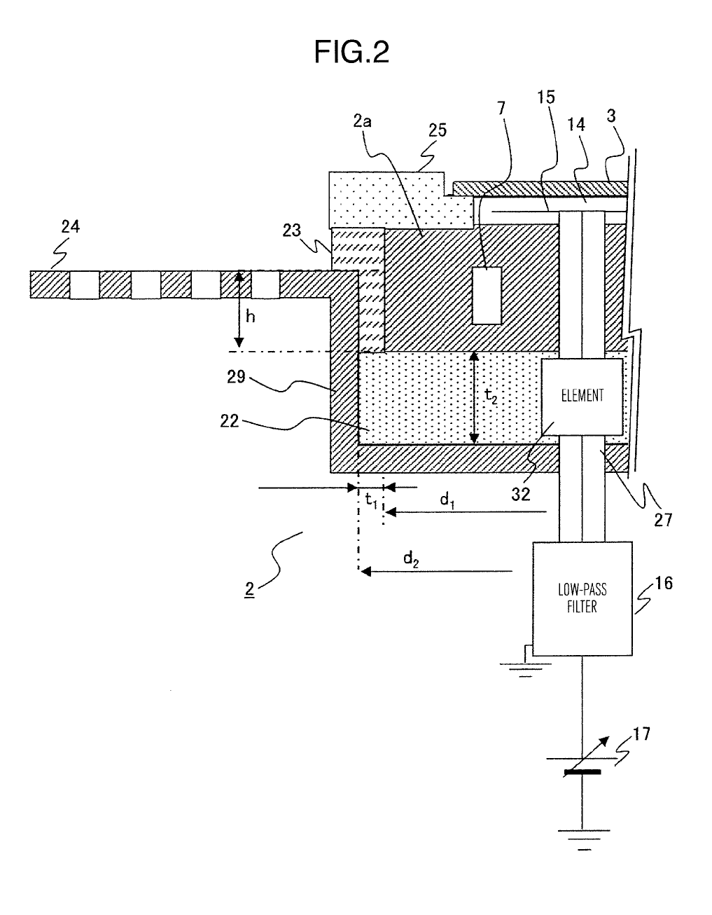

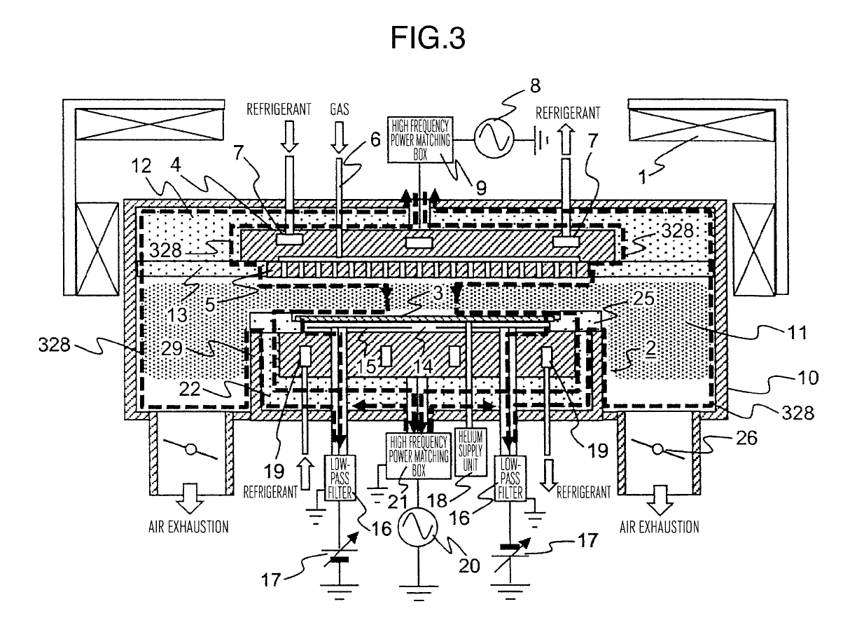

FIG. 3 is a cross sectional view showing an outline configuration of a plasma processing apparatus according to a comparative example that does not include a portion of the configuration of the embodiment shown in FIG. 1. The plasma processing apparatus shown in FIG. 3 does not include the confinement plate 24, the insulating layer 23, and the element 32 in a plasma processing apparatus according to the present embodiment and the other configurations are similar to those shown in FIG. 1. Descriptions of configurations equivalent to those of the embodiment in FIGS. 1 and 2 are omitted.

FIG. 3 is also a cross sectional view schematically showing a path through which a current of high frequency power for plasma formation flows in the plasma processing apparatus. In FIG. 3, a path 328 through which a high frequency current for discharge flows is schematically shown by using a dotted line.

In the plasma processing apparatus shown in FIG. 3, a path of current through which high frequency power to form plasma in the processing chamber flows from the upper electrode 4 through the shower plate 5 to the sample stage 2 across the plasma 11 as a dielectric formed in the processing chamber is constituted. As shown in FIG. 3, the element 32 is not included and if the impedance of the feeding path 27 to the tungsten electrode 15 or the feeding path to the base material 2a is relatively small, as shown by the path 328 through which a high frequency current for discharge flows indicated by a broken line in FIG. 3 a current of high frequency power output from the high frequency power supply for discharge 8 flows to the sample stage 2 on which the sample 3 is mounted and then, due to a high frequency, propagates on the top surface of the mounting surface of the sample stage 2 or through the sample 3 and further propagates between the undersurface of the base material 2a and the insulating plate 22 (surface of the undersurface of the base material 2a) from the susceptor 25 arranged on the outer circumferential side and the side face of the base material 2a to reach the center of the undersurface of the base material 2a. Further, the current passes on the surface on the inner side of a member constituting the vacuum chamber directly below the sample stage 2 and reaches the high frequency power supply for discharge via the coaxial cable as a feeding path of high frequency power for plasma formation arranged in an upper portion of the vacuum chamber 10 to form a closed circuit.

In the example in FIG. 3, the confinement plate 24 is not included and high frequency power for plasma formation propagating on the sidewall or the undersurface of the base material 2a is inhibited from forming a current path from the sidewall of the base material 2a whose side or lower surface is surrounded and covered with an insulating material such as Teflon to the outer circumferential side. Thus, the high frequency current having flown to the undersurface of the base material 2a flows toward the high frequency power matching box for bias 21 by passing through the low-pass filter 16 connected downward from a cable via the cable as the feeding path 27 of DC power to the tungsten electrode 15 for electrostatic chuck passed through the undersurface of the base material 2a or the coaxial cable as a feeding path of high frequency power for bias connected to the undersurface of the base material 2a.

A portion of the current of high frequency power for plasma formation having flown to the top surface of the sample stage 2 flows directly from the tungsten electrode 15 inside the electrostatic chuck film 14 to the feeding path 27 to flow into the grounded low-pass filter 16 below. The amount of current of high frequency power for plasma formation flowing into the low-pass filter 16 and the high frequency power matching box for bias 21 is suppressed by setting a sufficiently high input impedance to the low-pass filter 16 and the high frequency power matching box for bias 21 (including cables of the feeding path 27 and the like connected to these units and to which power is supplied), but if the frequency of the VHF band or higher is used as a high frequency for discharge, stray capacitance or parasitic inductance in the circuit or connection cable through which the current flow has a significant influence and it becomes difficult to realize a sufficiently high input impedance (in the present embodiment, 200 MHz is used as the high frequency for discharge and thus, the input impedance of 100Ω or more for 200 MHz) in a stable manner.

If, for example, a coaxial cable used as the cable connecting the sample stage 2 and the low-pass filter 16, even if the length of the cable is about 10 cm, the electrostatic capacity between a cable core wire and a shielding wire is about 10 pF, leading to an impedance of about 80Ω to the ground for 200 MHz. Further, parasitic impedance in the low-pass filter 16 has an influence and therefore, it is very difficult to realize an input impedance of 100Ω or more for 200 MHz. Moreover, the input impedance fluctuates relatively widely under the influence of variations of element constants in each circuit and arrangement of wires.

Thus, power input into the plasma 11 after being output from the high frequency power supply for discharge 8 fluctuates under the influence of variations of the input impedance of the low-pass filter 16 and the high frequency power matching box for bias 21 (including cables connecting these units to the sample stage 2) for high frequency power for plasma formation or the impedance of the feeding path 27 to the tungsten electrode 15 as an electrode for electrostatic chuck or the feeding path to the base material 2a as a lower electrode forming a bias potential of the wafer 3 being processed. In the comparative example, therefore, fluctuations of power input into the plasma 11 appearing due to fluctuations of the amount of current effectively flowing via the plasma 11 degrade reproducibility of conditions for processing the wafer 3 or cause performance differences between apparatuses.

Hereinafter, both of FIGS. 1 and 2 are used for the description. The present embodiment includes, as described above, the insulating layer 23 in a ring shape arranged by connecting to and surrounding the outer circumference of the sidewall of the base material 2a of the sample stage 2 and formed from a material of dielectrics such as ceramics with a high dielectric constant (dielectric constant 4 or more). The present embodiment also includes the conductive plate 29 at the ground potential having the base material 2a and the insulating layer 23 in a ring shape and also the insulating plate 22 in a disc shape arranged below by being in contact with the undersurface thereof inside the recess in the center portion and arranged by the side face of the insulating plate 22 and the insulating layer 23 being surrounded by the sidewall of the recess and the confinement plate 24 as a unit on the outer circumferential side thereof extending from the center portion to the outer circumferential side and a whose tip is close to or in contact with the inner wall surface of the processing chamber of the vacuum chamber 10. Though not illustrated, the conductive plate 29 in the present embodiment is set to the ground potential by being grounded or electrically connected to a ground.

The conductive plate 29 is formed from a conductive material, but the confinement plate 24 facing plasma has at least a member formed from a conductive material such as aluminum and an anodized aluminum film or a film formed by a material of dielectrics such as ceramics being sprayed on the surface thereof. As described above, the confinement plate 24 has a plurality of gas passage holes 30 formed therein and is configured such that a process gas supplied from the shower plate 5 or particles of plasma or products in the processing chamber pass through the inside of the gas passage holes 30 to flow through the space in the processing chamber on the outer circumferential side of the sample stage 2 toward a discharge opening below the sample stage 2.

Further, the element 32 including a resistor or coil is arranged on a feeding path including the feeding path 27 electrically connecting the DC power supply 17 for electrostatic chuck and the tungsten electrode 15 and a coaxial cable electrically connecting the high frequency power supply for bias 20 and the base material 2a. In the present embodiment, the element 32 arranged between the low-pass filter 16 and the tungsten electrode 15 on the feeding path 27 is configured as a resistor of 1000Ω and the element 32 arranged between the high frequency power matching box for bias 21 and base material 2a on the feeding path between the high frequency power supply for bias 20 and the base material 2a is an element having an inductance of 0.5 μH (element having an impedance of 628Ω for power of 200 MHz used for high frequency power for plasma formation), for example, an element including a coil.

In the present embodiment, the thickness and the height (t1 and h in FIG. 2 respectively) of a ring-shaped portion of the insulating layer 23 arranged between the side face of the base material 2a in a disc shape or a cylindrical shape and the sidewall of the recess of the conductive plate 29 at the ground potential in FIG. 2 and the dielectric constant of the insulating layer 23 are selected such that the electrostatic capacity C of the insulating layer 23 formed from a material having the value of the dielectric constant of 4 or more becomes about 500 pF based on the approximation of Formula (1). More specifically, alumina whose dielectric constant is 23 is selected for the insulating layer 23, t1 is set to 3.5 mm, and h is set to 20 mm. The insulating plate 22 arranged between the base material 2a and the conductive plate 29 is arranged by selecting the material (having a relatively small electrostatic capacity) having an impedance higher than that of the insulating layer 23 and dimensions such as the thickness to realize insulation outside the feeding path between the base material 2a and the conductive plate 29.

Further, the plasma processing apparatus according to the embodiment shown in FIGS. 1 and 2 is intended to perform etching of a wafer of 300 mm in diameter and the outside diameter (d1 in FIG. 2) of the base material 2a having a cylindrical shape inside the sample stage 2 is set to 330 mm. ∈ is the dielectric constant (∈=10) of the insulating layer 23. In Formula (1), the unit of d1, t1, and h is cm and the unit of C is F. The actual value of C changes slightly depending on dimensional accuracy of each unit and the gap present between the insulating layer 23 and the side face of the sample stage 2 or the conductive plate 29 at the ground potential, but can roughly be estimated by Formula (1)

C=8.854×10⁻¹⁴×(∈π(d1+t1/2)h/t1) (1)

In the present embodiment illustrated in FIGS. 1 and 2, the impedance Z of a high frequency for discharge f (200 MHz in the present embodiment) ranging from the side face of the sample stage 2 to the conductive plate 29 at the ground potential arranged therearound is determined to be about 1.6Ω from Formula (2) using the determined value of C.

Z=1/(2πfC) (2)

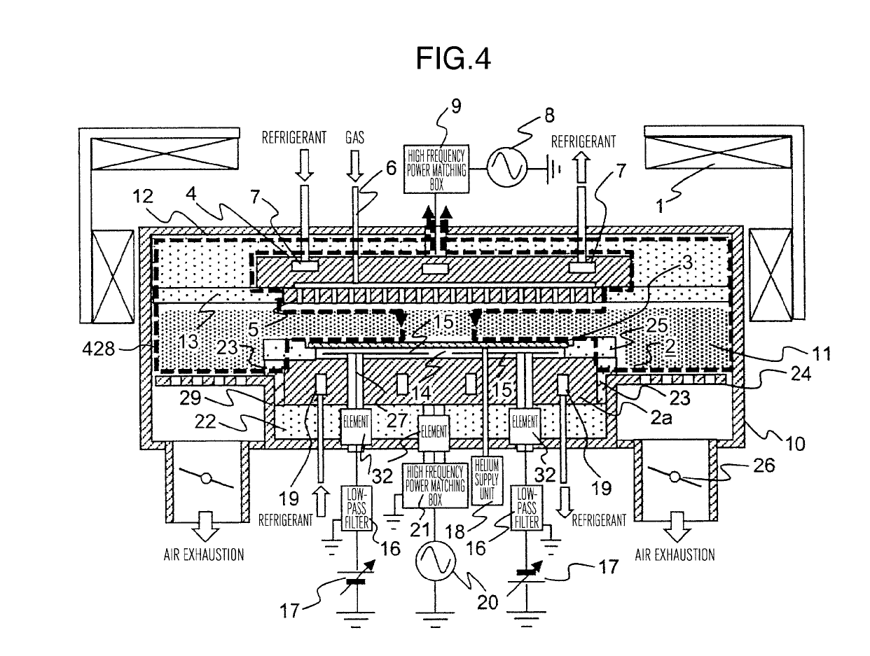

In such a configuration, as shown in FIG. 4, with the confinement plate 24 constituting a portion of the conductive plate 29 at the ground potential extending from the sidewall of the sample stage 2 to the outer circumferential side and the tip thereof being in contact with the wall surface on the inner side of the processing chamber in a cylindrical shape or arranged in a neighboring position with a slight gap, a current of high frequency power for plasma formation output from the high frequency power supply for discharge 8 and flowing to the sample stage 2 where the sample 3 is mounted on the mounting surface via the plasma 11 supplied into the processing chamber after passing through the upper electrode 4 and the shower plate 5 flows from the side face of the sample stage 2 to a member of the vacuum chamber 10 constituting the inner sidewall of the processing chamber via the surface of the confinement plate 24 set to the ground potential and the plasma 11 in contact with the surface via a sheath. The current flowing through the sidewall member of the vacuum chamber 10 passes through a cap member made of metal constituting an upper portion of the vacuum chamber 10 and flows to the high frequency power supply for discharge 8 via the coaxial cable electrically connected to the high frequency power supply for discharge 8 and the high frequency power matching box for discharge 9 arranged above the cable and further up to the ground (ground electrode) to form a closed path 428 through which a current of high frequency power for plasma formation flows.

As the input impedances of the feeding path 27 for electrostatic chuck connected to the sample stage 2 and the feeding path of high frequency power for bias, as described above, the elements 32 having a resistor of 1000Ω and an inductance of 0.5 μH (impedance of 628Ω for 200 MHz) are arranged in series by being contained in the insulating plate 22 on the inner side of the recess between the low-pass filter 16 and the tungsten electrode 15 and between the high frequency power matching box for bias 21 and base material 2a respectively. In the present embodiment shown in FIGS. 1, 2, and 4, the magnitude of impedance of the path 428 constituted by passing through the sidewall member of the vacuum chamber 10 from the side face of the sample stage 2 or the base material 2a via the confinement plate 24 and through which a current of high frequency power for plasma formation flows is set to a value of about 1/300 to 1/500 of the impedance of the above feeding path.

In the present embodiment, the impedance of the current path from the sample stage 2 via the confinement plate 24 (or the plasma 11) is predominantly the impedance of the insulating layer 23. In the present embodiment including the values of d1, t1, h, and C described above, the impedance becomes about 2Ω or less and thus, the impedance of the insulating layer 23 is a value about 1/300 of the impedance of the element 32, which is extremely small. Accordingly, the current of high frequency power for plasma formation flows through the path 428 from the sample stage 2 to the vacuum chamber 10 by passing through the confinement plate 24 with a relatively sufficiently small impedance in a stable manner.

In the present embodiment, therefore, a current of high frequency power for plasma formation at 200 MHz having flown to the top surface of the sample stage 2 or the sample 3 as output from the high frequency power supply for discharge 8 after passing through the cable for supply and being supplied into the processing chamber from the upper electrode 4 via the shower plate 5 is transmitted from the sidewall surface of the base material 2a to the sidewall of the recess of the conductive plate 29 via the insulating layer 23 after passing through the top surface of the sample stage 2 or the sample 3 and also transmitted from the tip portion of the confinement plate 24 to the wall surface in the processing chamber via the confinement plate 24 or the plasma 11 facing the confinement plate 24 to flow through a closed circuit that returns to the high frequency power supply for discharge 8 in a stable manner and is inhibited from flowing to the feeding path 27 connected to the tungsten electrode 15 in an upper portion of the sample stage 2 or to the feeding path connected to the base material 2a. By being able to form such a current path, degradation of reproducibility of sample processing and an occurrence of differences between apparatuses can be suppressed.

In the present embodiment, while the impedance of a resistor or an inductance element inserted into various circuits in series connected to the sample stage 2 is set to about 628 to 1000Ω, a similar effect can also be achieved for a frequency for discharge if the impedance is 1000Ω or more. Also, while the electrostatic capacity between the side face of the sample stage 2 and the conductive plate 29 at the ground potential via the insulating layer 23 is set and the impedance thereof is set to about 1.6Ω for a frequency for discharge, a similar effect can also be achieved if the impedance is 10Ω or less.

A resistance element of 1000Ω is selected as the resistor or the inductance element connected to the DC power supply for electrostatic chuck. This is because the electrostatic chuck film usually has a resistance of 1 MΩ or more and even if a resistor is inserted in series, a DC potential of the DC power supply 17 can sufficiently be provided to the electrostatic chuck film. Therefore, the resistance to be inserted may be up to about 1/10 of the resistance of the electrostatic chuck film (100 kΩ in the case of 1 MΩ).

A similar effect can also be achieved by inserting an inductance element to be an impedance of 100Ω or more for a high frequency for discharge without using a resistor as an element inserted into the electrostatic chuck circuit. On the other hand, if a resistor is used as a resistor or an inductance element connected to the power supply for bias 20, a power loss is generated.

Therefore, the element inserted into a connection circuit of the power supply for bias 20 is desirably an inductance element without a power loss. While the value of the inductance element inserted into the connection circuit of the power supply for bias 20 is set to 0.5 μH in the present invention, a similar effect can also be achieved by an inductance element of 0.08 μH or more that produces an impedance of about 100Ω for a high frequency for discharge.

An increasing electrostatic capacity (a decreasing impedance) between the side face of the sample stage 2 and the conductive plate 29 at the ground potential via the insulating layer 23 is advantageous in terms of forming a current path of high frequency power for plasma formation, but acts similarly on a high frequency power supply for bias and thus, if the electrostatic capacity is made too large, a reactive current of the high frequency power supply for bias increases and a power loss increases, which is not desirable. In the present embodiment, 4 MHz is used for the high frequency power supply for bias 20.

Thus, the impedance between the side face of the sample stage 2 and the conductive plate 29 at the ground potential when viewed from high frequency power for bias becomes about 80Ω. The impedance between the side face of the sample stage 2 and the conductor at the ground potential for high frequency power for bias is desirably about 50Ω or more and if the impedance is 50Ω or less, particularly when a high voltage amplitude (for example, the voltage amplitude of 1000 V or more) is applied, a loss caused by a reactive current becomes relatively large, leading to lower power application efficiency or a failure accompanying heating of a high frequency power path. From the above, the impedance between the side face of the sample stage 2 and the conductor at the ground potential via the insulating layer 23 is desirably 10Ω or less for a high frequency for discharge and 50 Ω or more for a high frequency for bias.

The resistor or inductance element 32 according to the present invention shown in FIG. 1 is desirably arranged as close to the sample stage 2, particularly the base material 2a as a material of conductor to which a high frequency power supply for bias is supplied or the tungsten electrode 15 to which DC power for electrostatic chuck is applied as possible. When high frequency power of a frequency of the VHF band or higher is used for the formation of plasma, the impedance for the high frequency power is noticeably changed even by a small amount of stray capacitance or parasitic inductance. This is because if the sample stage 2 and the resistor or inductance element 32 are connected by a long coaxial cable, the earth capacity of the cable or the like becomes a dominant factor of the impedance for a high frequency for discharge, which makes it difficult to secure an intended impedance.

In the embodiment shown in FIGS. 1 and 2, while 200 MHz is used for the high frequency power supply for discharge 8 and 4 MHz is used for the high frequency power supply for bias 20, a similar effect can also be achieved by using a frequency of VHF band (30 MHz to 300 MHz) or more for a high frequency power supply for discharge and a frequency in the range of 100 kHz to 14 MHz for the high frequency power supply for bias. Alumina is used for the insulating layer 23, but in addition, insulating materials such as quartz, yttria, or aluminum nitride may also be used and the above operation can be achieved in all cases by adjusting the impedance between the side face of the base material 2a and the conductive plate 29 at the ground potential via the insulating layer 23 to 10Ω or less for high frequency power for plasma formation and 50Ω or more for high frequency power for bias.

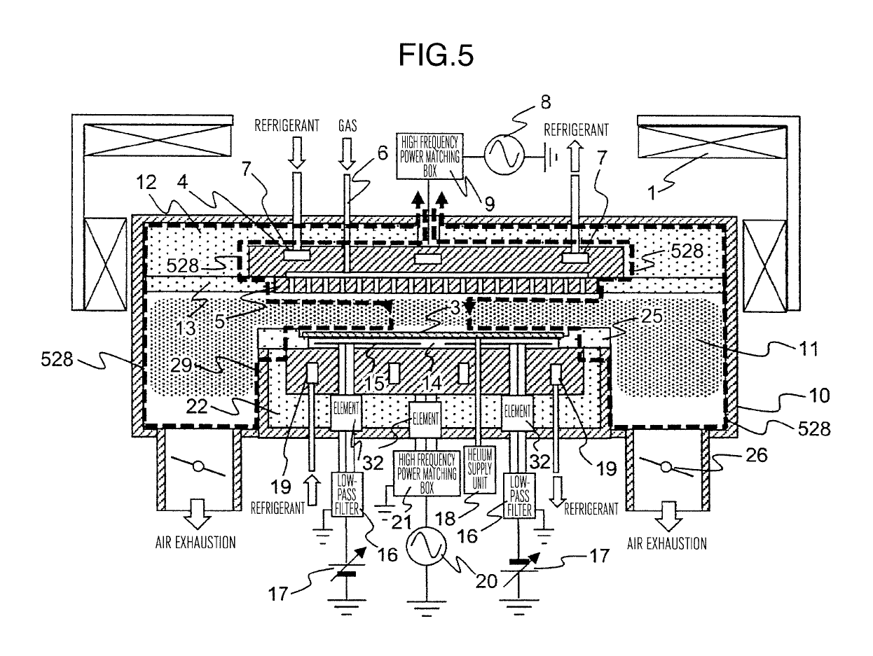

A modification of the above embodiment is shown in FIG. 5. FIG. 5 shows a case when the confinement plate 24 used in the embodiment in FIG. 1 is not included.

That is, the conductive plate 29 forming the sidewall of the sample stage 2 in the present example does not include the confinement plate 24 extending from the center in the direction of the outer circumferential side on the outer circumferential side of the sample stage 2 in a cylindrical shape included in the embodiment in FIG. 1. In other words, a member made of conductor, to which the ground potential is set, and in contact with the plasma 11 is not arranged in a space on the outer circumferential side of the sidewall of the sample stage 2 and between the sidewall of the sample stage 2 and the inner sidewall of the processing chamber. The plasma 11 is in contact with the sidewall of the sample stage 2 and the inner sidewall of the processing chamber.

Also in this example, a current of high frequency power for plasma generation considered to be supplied from the upper electrode 4 and the shower plate 5 into the processing chamber and to flow to the top surface of the sample stage 2 or the wafer 3 via the plasma 11 as a dielectric flows from the sidewall of the base material 2a to the conductive plate 29 constituting the sidewall of the sample stage 2 arranged across the sidewall and an upper member in a ring shape of an outer circumferential edge of the insulating plate 22. Also in this example, as a result of appropriately selecting the material of the upper member in a ring shape of the outer circumferential edge of the insulating plate 22 and dimensions such as the thickness thereof, the input impedance of the upper member for the high frequency power for plasma formation is set to 1/300 or less of the impedance of the feeding path between the feeding path 27 or the base material 2a and the high frequency power supply for bias 20. Accordingly, the flow of a current for plasma formation from the sample stage 2 to the DC power supply 17 the high frequency power supply for bias 20 by passing through these feeding paths is suppressed.

A path 528 through which a current of high frequency power for plasma formation returning from the sample stage 2 to the high frequency power supply for discharge 8 is a path that passes through the inner wall surface of the processing chamber from the surface of a member as a lower portion of the vacuum chamber 10 connected to the conductive plate 29 as a sidewall of the sample stage 2 and constituting the undersurface (inner sidewall surface) of the processing chamber and, like the embodiment in FIG. 1, returns to the high frequency power supply for discharge 8 from the inner surface of the member constituting the upper portion of the vacuum chamber 10 through the feeding path such as a coaxial cable connecting the high frequency power supply for discharge 8 connected to the inner surface and the upper electrode 4. The member constituting a path allowing such a current to flow may not be the confinement plate 24 shown in FIG. 1 and like the example shown in FIG. 5, a similar operation can also be achieved by the conductive plate 29 facing the plasma 11 or a member made of conductor as a portion of the vacuum chamber 10 and constituting the inner sidewall of the processing chamber. In the present example, the conductive plate 29 and the vacuum chamber 10 are grounded to set the same potential as that of the ground.

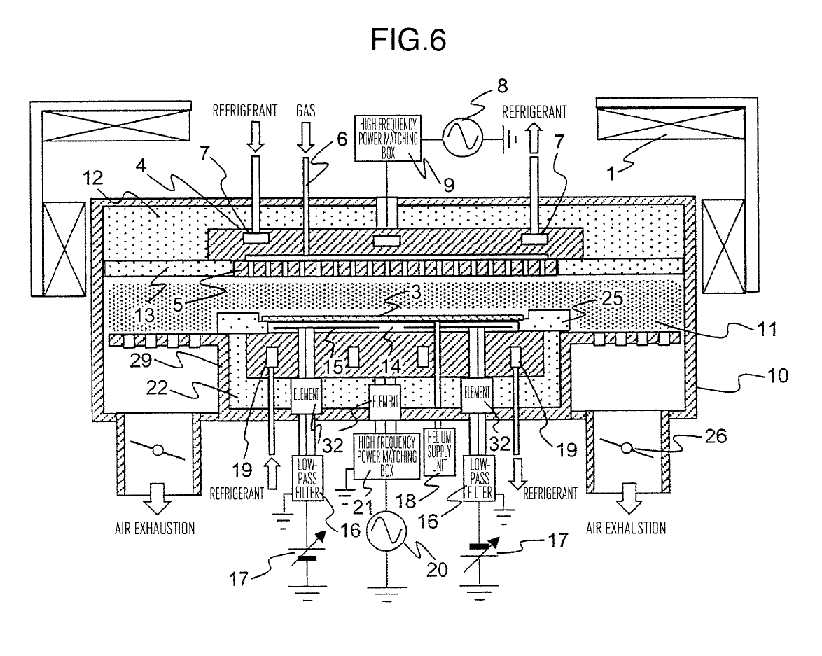

Next, another modification of the above embodiment is shown in FIG. 6. In the embodiment in FIG. 6, in the plasma processing apparatus shown in FIG. 1, instead of the configuration in which the insulating plate 22 and the insulating layer 23 are vertically arranged, the insulating plate 22 is arranged in a location where the insulating layer 23 is arranged to form a member and a capacitor 31 is arranged on a circuit electrically connecting the inner side of the recess of the conductive plate 29 set to the ground potential and the undersurface of the base material 2a.

In the present example, the four capacitors 31 are arranged in locations forming an equal angle or an angle approximated to the extent allowing considering to be equal with respect to sides of the base material 2a in the sample stage 2 when viewed from above. The capacitors 31 whose total capacity is 400 pF (100 pF for each capacitor) are used. The example in FIG. 6 is a structure when the impedance necessary for the side structure of the sample stage 2 disclosed in FIG. 1 cannot be secured.

The present example can achieve the same operation as the embodiment shown in FIG. 1 by the capacitors 31 being arranged between the base material 2a and the recess of the conductive plate 29 at the ground potential by electrically connecting the base material 2a and the recess. Also, by arranging the capacitors 31 in locations that mutually form an equal angle in the circumferential direction of the sample stage 2 having a cylindrical shape regarding the center thereof, paths through which high frequency power for plasma formation flows out from the sample stage 2 or the amount of power flowing out through these paths is inhibited from being unbalanced in the circumferential direction.

By setting the total capacity of a plurality of the arranged capacitors 31 so as to have the same value of impedance as that of the insulating layer 23 in the embodiment shown in FIG. 1 or an approximated one, like the relevant embodiment, high frequency power for plasma generation flows through a closed circuit that, after being output from the high frequency power supply for discharge 8, passes through the sidewall of the processing chamber after the base material 2a via the capacitor 31 and the confinement plate 24 before returning to the original high frequency power supply for discharge 8 in a stable manner and is inhibited from flowing to the feeding path 27 connected to the tungsten electrode in an upper portion of the sample stage 2 or to the feeding path connected to the base material 2a so that degradation of reproducibility of sample processing and an occurrence of differences between apparatuses can be suppressed. In the example shown in FIG. 7, the total capacity of the capacitors 31 is set to 400 pF, but as shown in the embodiment, the capacity only needs to yield the impedance of 10Ω or less for the high frequency power for plasma formation at 200 MHz and the impedance of 50Ω or more for the high frequency power for bias and an element other than the capacitor may also be selected.

In the examples shown in FIGS. 1, 5, and 6, the element 32 including a resistor or coil is inserted on a feeding path from the DC power supply 17 for electrostatic chuck and the high frequency power supply for bias 20 connected to the sample stage 2 and if the sample stage 2 includes a heater and also a path for feeding, like the above examples, the above operation can be achieved by arranging the element 32 on the path.

According to the above embodiments, as described above, when plasma is generated at a high frequency in the VHF band or higher superior in plasma generation characteristics in a wide range of pressure by a manufacturing apparatus of a semiconductor device, particularly a plasma processing apparatus such as a plasma etching apparatus that performs etching of a film structure below using a circuit pattern for etching formed by the lithography technology as a mask, the influence of a current of high frequency power for plasma generation can be suppressed so that stable plasma generation can be realized. Accordingly, degradation of reproducibility of processing by the plasma processing generation and an occurrence of differences between apparatuses can be suppressed.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a processing chamber arranged inside a vacuum chamber;
a sample stage arranged in the processing chamber and on a top surface of which a sample to be processed is mounted;
an upper electrode arranged above the sample stage and opposite to the top surface of the sample stage to supply an electric field to generate plasma in the processing chamber;
a first high frequency power supply electrically connected to the upper electrode to output first high frequency power to form the electric field;
a lower electrode arranged inside the sample stage and to which second high frequency power whose frequency is lower than the frequency of the first high frequency power is supplied while the sample being processed;
a second high frequency power supply connected to the lower electrode to supply the second high frequency power via a feeding path for bias;
an electrode for electrostatic chuck arranged in an upper portion of the sample stage and inside a dielectric film constituting a mounting surface and to which DC power is supplied via a feeding path for electrostatic chuck arranged inside the lower electrode; and
a conductive plate arranged by surrounding an outer circumference of the lower electrode across an insulating layer, facing plasma on an outer circumferential side of the sample stage, and to which a ground potential is set, wherein
the insulating layer has an impedance smaller than the impedance of the feeding path for bias or the feeding path for electrostatic chuck for the first high frequency power and a current of the first high frequency power flows through a circuit that passes through the conductive plate and a member constituting an inner sidewall surface of the processing chamber from the upper electrode via the top surface of the sample stage to return to the high frequency power supply.

2. The plasma processing apparatus according to claim 1, further comprising:
a grounded low-pass filter arranged on the feeding path for bias and in a matching box that matches power from the second high frequency power supply or on the feeding path for electrostatic chuck to prevent the current of high frequencies.

3. The plasma processing apparatus according to claim 1, further comprising:
an element arranged on the feeding path for bias or the feeding path for electrostatic chuck, wherein the impedance for the first high frequency power including the element on the relevant feeding path is made larger than the impedance of the insulating layer for the first high frequency power.

4. The plasma processing apparatus according to claim 2, further comprising:
an element arranged between the matching box and the lower electrode on the feeding path for bias or an element arranged between the low-pass filter and the electrode for electrostatic chuck on the feeding path for electrostatic chuck, wherein the impedance for the first high frequency power including the element on the relevant feeding path is made larger than the impedance of the insulating layer for the first high frequency power.

5. The plasma processing apparatus according to claim 3, further comprising:
an insulating plate arranged below the lower electrode to insulate the lower electrode, wherein the element is arranged inside insulating plate.

6. The plasma processing apparatus according to claim 1, wherein
the impedance of the feeding path for bias or the feeding path for electrostatic chuck is set to 100Ω or more.

7. The plasma processing apparatus according to claim 1, wherein
the frequency of the first high frequency power is between 30 MHz and 300 MHz in a VHF band.

8. The plasma processing apparatus according to claim 7, wherein
the frequency of the second high frequency power is between 100 kHz and 14 MHz.
